(19) United States
(12) Patent Application Publication
(10) Pub. No.: US 2009/0236658 A1
(43) Pub. Date: Sep. 24, 2009

(54) ARRAY OF VERTICAL TRIGATE TRANSISTORS AND METHOD OF PRODUCTION

(75) Inventor: Ulrike Gruening-von Schwerin, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/050,230

(22) Filed: Mar. 18, 2008

(51) Int. Cl. H01L 29/78; H01L 21/336

(52) U.S. Cl. 257/331; 438/270; 257/E29.262; 257/E21.41

(57) ABSTRACT

An array of vertical trigate transistors and method of production are disclosed. One embodiment provides an array of selection transistors for selecting one of a plurality of memory cells. A selection transistor is a vertical trigate transistor.

### BACKGROUND

The invention relates to an array of vertical transistors to select one of a plurality of resistively switching memory cells and a method for forming an array of vertical transistors.

In resistively switching memory cells, for example phase change random access memory (PCRAM), the information is stored in a volume of switching active material, wherein the switching active material may switch between two states. In a first state the switching active material may have a high resistivity, i.e. a low conductivity, and a lesser resistivity, i.e. a higher conductivity, in a second state. Accordingly, the information of a bit may be assigned to a PCRAM cell, wherein the state of the cell reflects the status of the bit. Although the invention is described for PCRAM cells in the following the structure and methods disclosed herein can be used for any random access memory including selection transistors, for example MRAM, CBRAM, TMO RAM or flash RAM.

For reading a resistively switching memory cell the state of the volume of phase change material is sensed, i.e. the conductivity is sensed. This can be achieved for example by applying a predefined voltage to the cell and sensing the amplitude of the current flowing through the cell. For switching the state of a resistively switching memory cell a high current is sent through the volume of switching active material in order to heat and subsequently change the material from a one state to the other. A selection transistor comprised in the cell thus should be able to send a strong current through the cell.

To be cost competitive, a small cell size and a cost competitive process is required for a memory product including resistively switching memory cells. Conventionally and to get a sufficient operating margin a 1T1R, i.e. one transistor (T) acting as switch per resistive memory element (R), or a 1D1R architecture, i.e. one diode (D) as switch per memory element, is used.

### SUMMARY

One aspect describes a structure and a corresponding manufacturing method for an integrated circuit including an array of selection transistors. The transistors are formed at least partially in a semiconductor substrate, and each transistor is suitable for selecting one of a plurality of memory cells. Each of the selection transistors includes a first source/drain region of a first conductivity type coupling the transistor to a source electrode, a second source/drain region of the first conductivity type coupling the transistor to a memory element, a channel region of a second conductivity type connecting the first source/drain region with the second source/drain region, wherein the channel region is arranged above the first source/drain region and below the second source/drain region and a gate electrode arranged at three sides of the channel region.

Furthermore, a manufacturing method for producing the integrated circuit including an array of transistors in a substrate for selecting one of a plurality of resistively switching memory cells is disclosed. The method includes providing a substrate, forming a plurality of parallel, auxiliary trenches in the trenches and filling the auxiliary trenches with a sacrificial material, forming a plurality of gate electrode trenches intersecting the auxiliary, filled trenches, wherein the sacrificial material in the auxiliary trenches is removed at intersections of auxiliary trenches and gate electrode trenches, forming an insulating liner at one sidewall of the gate electrode trenches, removing the sacrificial material from the auxiliary trenches, the portions of the auxiliary trenches thus forming protrusions of the gate electrode trenches, forming first source/drain regions in the bottom of the gate electrode trenches, forming gate electrodes in the gate electrode trenches and their protrusions, forming second source/drain regions in the substrate material located between the protrusions of the gate electrode.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic circuit diagram of two memory cells representing an array of several memory cells.

FIGS. 2a, 2b illustrate a schematic top-down view onto a cutout of a layout of an array of memory cells and a cross sectional view.

FIGS. 3a, 3b, 3c illustrate a top-down view on and cross sectional views through an array of transistors in an early processing stage.

FIGS. 4a, 4b, 4c illustrate a top-down view on and cross sectional views through the chip after etching word line trenches.

FIGS. 5a, 5b, 5c illustrate a top-down view on and cross sectional views through the chip before forming the word lines.

FIGS. 6a, 6b, 6c illustrate a top-down view on and cross sectional views through the chip after forming the selection transistors.

FIGS. 7a, 7b, 7c illustrate a top-down view on and cross sectional views through the chip after forming the memory elements and bit lines.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

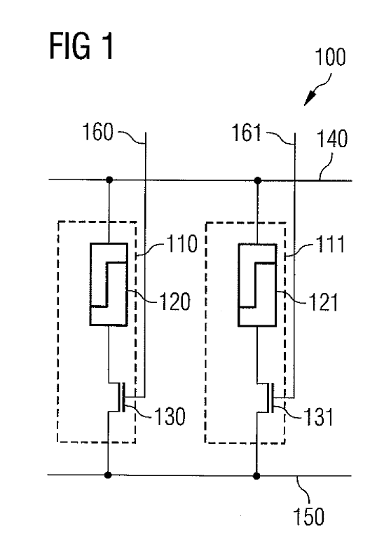

FIG. 1 illustrates an electrical circuit 100 including a first and a second memory cell, 110, 111, which exemplify a plurality of identical memory cells arranged in an array. Each cell includes a volume of switching active material, i.e. a resistive memory element 120, 121, and a selection transistor 130, 131. Each memory element 120, 121 is coupled with its one end to a bit line 140 and with its residual end to the drain of a selection transistor. In this embodiment the source of the selection transistors 130, 131 is coupled to line 150, which for example may be a common ground plate shaped like a mesh. The gate of a selection transistor 130, 131 is coupled to word line 160 and 161 respectively.

In one embodiment line 150 may be coupled to ground potential, such that line 150 is a ground line. In alternative embodiments line 150 may be coupled to ½ Vdd and the drain may change between Vdd and ground potential, such that a transistor can be operated bidirectional. In the embodiments disclosed hereinafter line 150 is coupled to ground potential in order to not unnecessarily obscure the description.

Line 150, which in this embodiment is shaped as a mesh, may be formed from any conducting, typically doped layer in the wafer and typically serves as a common line, for example a common ground line, for all memory cells. As the layer typically is arranged below the level of the original surface of the wafer line 150 is buried. In one embodiment line 150 may be a plate electrode, which may be formed from another material, including metal silicides and metals, for example. The semiconductor material, in which the above-noted transistors are formed, may then be deposited, epitaxially regrown, or otherwise formed thereon.

The exemplified memory cells represent a plurality of memory cells of a memory device, wherein the cells are arranged in an array with a plurality of bit lines and word lines for operating the cells. A plurality of memory cells may be coupled to one bit line and a plurality of memory cells is coupled to one word line, wherein an individual memory cell is coupled to a pair of one bit line and one word line, such that one cell can be selected by the appropriate word and bit line.

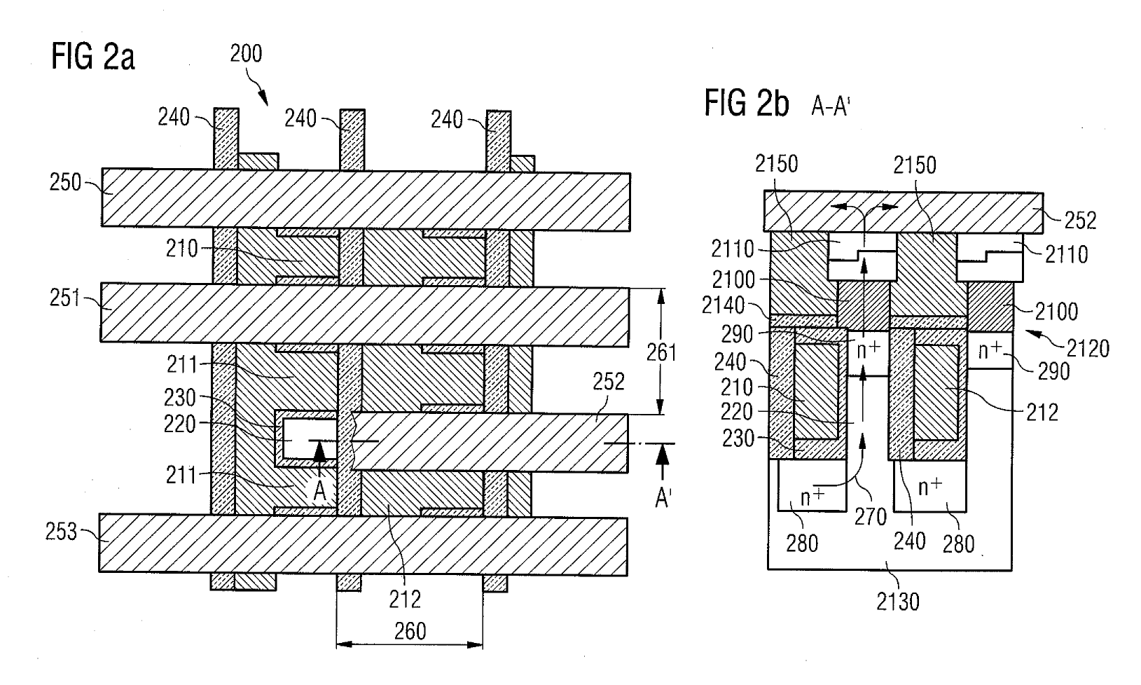

FIGS. 2a and 2b schematically illustrate the architecture of an array of memory cells including selection transistors, wherein FIG. 2a illustrates a top-down view onto a cut-out of a layout of an array 200 of memory cells including trigate selection transistors and wherein FIG. 2b illustrates a cross-sectional view parallel to a bit line and through two exemplifying memory cells.

In this drawing the insulation material separating and insulating adjacent elements is partly omitted for reasons of clearness. It is apparent to those skilled in the art that elements, for example such as bit lines or intersecting word lines, are embedded in a suitable dielectric to galvanically insulate these from each other. Furthermore some elements, which are comprised in a resistively switching memory cell, for example such as volumes of resistively switching material, are not illustrated, as they are hidden by other elements located above them.

FIG. 2a illustrates a schematic top down view on an array 200 of memory cells. Reference numeral 210 denotes a word line, which forms the gate electrode. As illustrated gate electrode 210 shapes protrusions 211, such that an active area 220 is surrounded at three sides by the gate electrode, wherein the active area 220 is insulated by gate oxide 230 from gate electrode 210 and its protrusions 211 respectively. The fourth side of active area 220 is insulated by a gate insulation dielectric 240, which may be formed of any dielectric material. As illustrated gate insulation dielectric 240 extends along and parallel to word line 210, insulates active areas 220 of memory cells coupled to the word line 210 as well as protrusions of the word line against the adjacent word line 212 and thus separates a column of memory cells coupled to a first word line 210 from an adjacent word line 212. The layer thickness of gate insulation dielectric 240 may be greater than the layer thickness of gate oxide 230. A gate voltage applied to adjacent word line 212 will not only effectuate a conducting channel in the memory cells coupled to the word line 212, but will also effectuate the active areas of memory cells coupled to word line 210. Due to the thicker layer of the gate insulation dielectric 240 the effect of the gate voltage on memory cells, i.e. selection transistors, coupled to word line 210 is much smaller than the effect on cells coupled to word line 212. That is a gate voltage applied to word line 212 will have a negligible effect on memory cells coupled to an adjacent word line 210.

A current flowing through active area 220, which in FIG. 2a flows perpendicular to the paper plane, is conducted to a memory element, i.e. a volume of resistively switching material, not illustrated in the top-down view, and is then discharged via bit line 252. Note that bit line 252 in this view is drawn incomplete in order to reveal the arrangement around active area 220.

Even though the figure is not drawn to scale arrows 260, 261 indicate the dimensions of a cell. The periodicity of word lines may be as small as 2F as indicated by 260 and the periodicity of bit lines 250-253 also may be as small as 2F, wherein F denotes the minimum feature size defined by the manufacturing method used. Consequently the size of the illustrative memory cell may be as small as 4F².

Also the approximate size of an active area is defined by the periodicity of the bit—and the word lines. According to current production capabilities a width of 1F is required for a bit- or a word line, thus the area of an active area is approximately 1F by 1 F resulting in an area of 1F². Advances in the art of metallurgy and lithography, among others, may change these relative dimensions.

The vertical structure of the arrangement is more precisely illustrated in FIG. 2b, which is a cross section along cut-line A-A′ through two memory cells formed in a substrate 2130 and coupled to two adjacent word lines 210, 212 and one bit line 252.

A gate voltage applied to word line 210 effectuates a conducting channel in active area 220, which in turn effectuates a current 270 to flow from the source implanted area 280, which forms a first source/drain region of a first conductivity type, through active area 220, which is of a second conductivity type, and in which a conducting channel is induced by the electrical field caused by the applied gate voltage. The current then enters a doped drain area 290 forming a second source/drain area of the first conductivity type, and then a bottom electrode contact 2100 and further flows into a volume of resistively switching material 2110. As mentioned above the volume of switching active material forms the memory element, because the conductivity of the material reflects the stored information. The current then leaves the switching active material for example via a top electrode contact or similar contact layers—not illustrated in the drawings—and is finally dissipated via bit line 252.

In one embodiment the word lines 210, 212 are located below the surface plane of the original substrate indicated by arrow 2120, thus the word lines and correspondingly the gate electrodes formed by the word lines are buried. In an alternative embodiment the word lines may vertically extend above the surface plane of the original substrate, but wherein the portion of the word lines forming the gate electrodes is arranged below the plane, such that the gate electrodes are buried. Accordingly the gate electrodes are buried in either architecture.

The surface plane of the original substrate as indicated by arrow 2120 forms a reference plane for geometric terms like vertical or below or above. Vertical shall mean the direction parallel to the normal vector of the reference plane and terms like above or below are used to describe elements positioned in sequence along the vector.

Reference numeral 2140 denotes a mid-of-line layer of any suitable insulating material, e.g., silicon nitride, and numeral 2150 denotes any insulating material, e.g., silicon oxide, which both electrically separate adjacent elements of the structure.

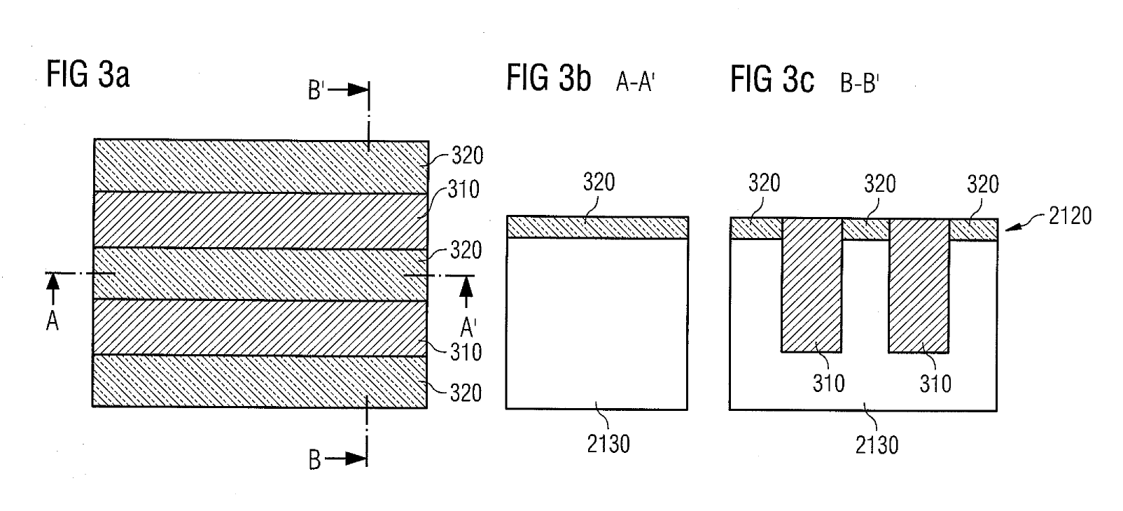

FIGS. 3a, 3b and 3c illustrate views of the memory device in an early manufacturing stage, wherein FIG. 3a is a top view, FIG. 3b illustrates a cross section along cut-line A-A′ i.e. parallel to a bit line, which will be produced later, and FIG. 3c illustrates a cross section along cut line B-B′ parallel to a word line, which also will be produced later.

In a manufacturing process, a layer of hardmask material 320 is deposited on substrate 2130 and shaped into lines by conventional lithographic processing. Subsequently the substrate material, i.e. for example the silicon of the wafer or die, is etched to form auxiliary trenches, which subsequently are filled with a sacrificial material 310, which may be any suitable insulating material, for example one of SiO₂, Al₂O₃ or SiGe.

FIG. 3b illustrates a cross sectional view along cut-line A-A′ i.e. parallel to a bit line and an auxiliary trench filled with a sacrificial material 310, and FIG. 3c illustrates a cross sectional view perpendicular to a bit line, that is along cut-line B-B′. After filling the auxiliary trenches with the sacrificial material 310 the surface of the wafer/die/chip maybe planarized for example by a chemical mechanical polishing (CMP) or etchback process. Optionally the hardmask maybe removed afterwards, wherein at least a comparatively thin layer remains on the top surface. The remaining hardmask material covers the substrate material 2130 and serves as a protective layer for the substrate material in subsequent processing, for example when removing material from the top surface of the chip.

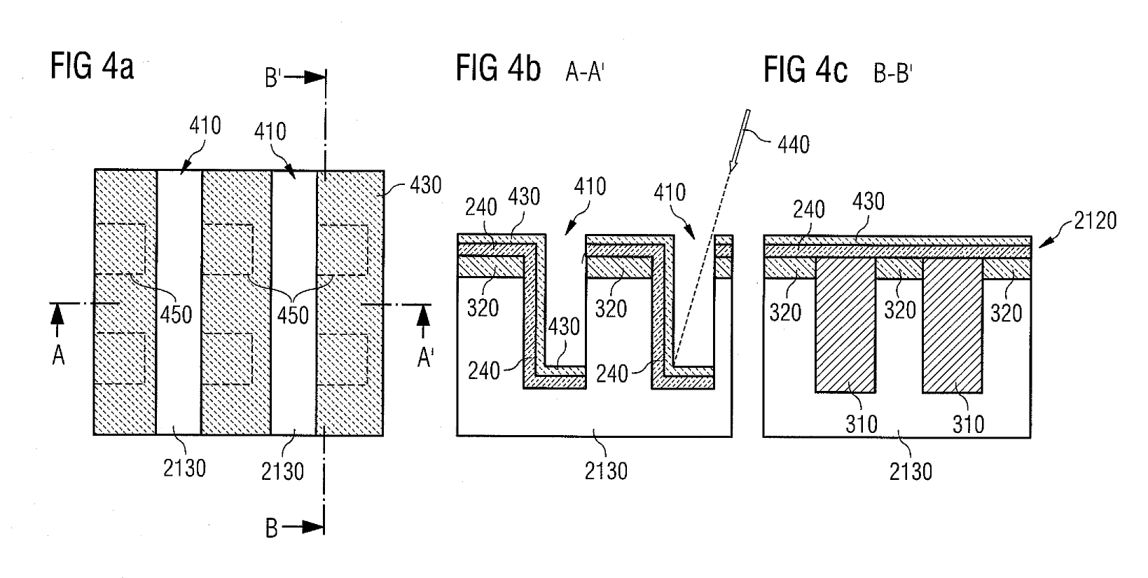

FIGS. 4a, 4b and 4c illustrate the views as in FIG. 3 after having performed further processing.

In further processing, word line trenches 410 perpendicular to the auxiliary trenches filled with sacrificial material 310 are etched. This can be done for example by depositing a suitable hard mask material and performing conventional etching processes to etch the trenches 410 through the silicon 2130 of the wafer and through the sacrificial material 310. The hard mask material, which in one embodiment may be nitride, maybe partially removed after the etching process. In the drawing this layer of hardmask material is not explicitly illustrated as it is placed on top of hard mask material 320.

In order to form a single sided insulation layer 240 in the word line trenches, that is an insulation layer 240 located at one sidewall of a word line trench, an insulating layer such as a nitride or oxide-nitride liner and a layer of undoped silicon 430 are formed on the chip. The nitride liner 240 and the layer of undoped silicon 430 cover the surface of the chip including the vertical sidewalls and the bottom of a word line trench 410. Then an angled boron (BF₂) implant is performed with an angle as indicated by arrow 440, wherein the angle is adjusted such that one sidewall is implanted preferentially over complete depth. In this way the polysilicon 430 located on horizontal top surfaces and on one vertical sidewall of each word line trench 410 is p+ doped, whereas the polysilicon located at the opposite sidewall remains largely undoped. Also the polysilicon located on the ground of a word line trench will be implanted at least partially, as the implanting angle scatters the dopant into the ground and dopant will be reflected from the sidewall into the ground.

Subsequently the undoped polysilicon is etched selectively to the doped polysilicon thus removing the undoped polysilicon from one vertical sidewall of each word line trench 410, wherein the etch process stops on the silicon 2130 of the die or the sacrificial material 310 or the nitride liner 240 or the hard mask material 320 respectively. The etching process may be a wet chemical etching. Optionally the doped polysilicon 430 can be oxidized such that it turns from conducting to insulating. Removing the undoped polysilicon from the vertical sidewall bares the nitride liner on the sidewall. The nitride liner is then removed selectively to the doped or (partially) oxidized silicon, i.e. the nitride liner is removed from the vertical sidewall of trench 410.

As illustrated in the top view of FIG. 4a this leaves the horizontal surfaces of the chip and also, as illustrated in FIG. 4b, at least one sidewall of a word line trench 410 covered with the layer of doped or oxidized polysilicon 430 on top of the nitride liner 240.

The areas 450 surrounded by the dotted lines illustrate the position of the auxiliary trenches filled with sacrificial material 310, which are separated from an adjacent word line trench by liner 240 and doped or oxidized silicon 430.

The cross sectional view 4c along cut-line B-B′, i.e. parallel to and through a word line 410 trench illustrates the crossing of the word line trench with an auxiliary trench filled with sacrificial material 310. Liner 240 and the oxidized and doped polysilicon 430 cover the left sidewall and the bottom of each word line trench 410.

Note that unlike as illustrated FIG. 4b the thickness of liner 240 may not be constant. Depending on the adjustment of the implantation angle and the amount of dopant scattered and reflected into the polysilicon on the ground of a word line the doping of the polysilicon may have a gradient, i.e. the doping of the polysilicon is higher close to the vertical sidewall and correspondingly decreases with increasing distance, such that the etching process does not remove the polysilicon evenly from the ground of a word line trench.

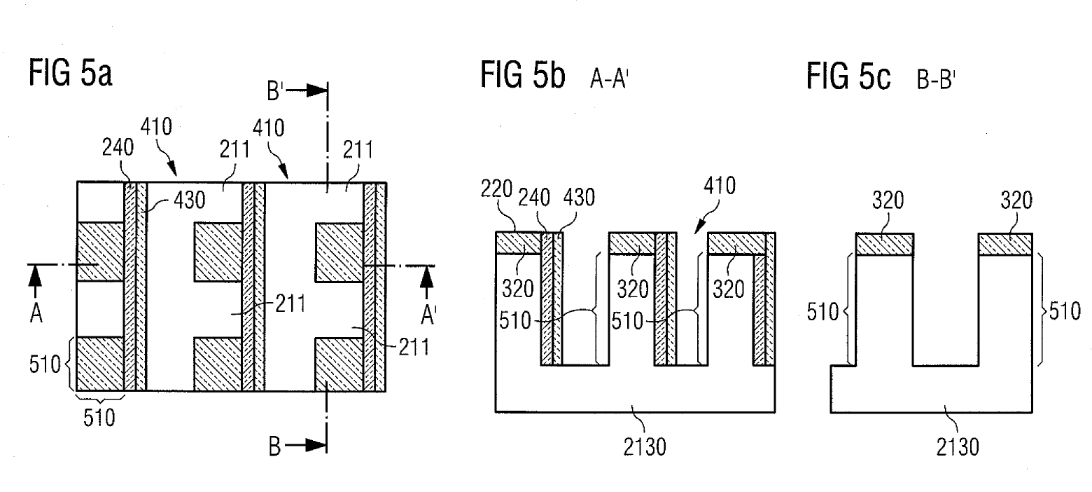

FIGS. 5a, 5b and 5c illustrate the views after the oxidized, boron doped polysilicon layer 430 and the insulating nitride liner 240 have been removed from the horizontal surfaces, which can be achieved by an anisotropic etching process. In an alternate way, the layers can be removed from the top surface at a later chemical mechanical polishing step, and are left at the bottom of the trench, which is not illustrated.

Subsequently the sacrificial material 310 has been removed, i.e. by etching the sacrificial material 310 selectively to the silicon 2130 and the insulating layers 240 and 430.

Removing the sacrificial material effectuates the formation of the protrusions 211 of the word line trench 410, i.e. the comb like shape of the word line trench as illustrated in the top view of FIG. 5a, wherein the protrusions 211 form the teeth of the comb. These protrusions of a word line trench are separated by insulating (nitride) liner 240 and the oxidized, doped polysilicon layer 430 from an adjacent word line.

FIG. 5b illustrates a cross sectional view along cut line A-A′ illustrating vertical pillars 510 of substrate 2130 between adjacent protrusions of the word line trench 410, such that a pillar is surrounded at two, opposite sides by protrusions of a word line trench, the third side abutting the word line trench 410 and the fourth side abutting liner 240.

FIG. 5c illustrates a cross sectional view along cut line B-B′. In this view the pillars 510 of substrate material are located in front of the insulating nitride liner 240, which separates two adjacent word line trenches 410.

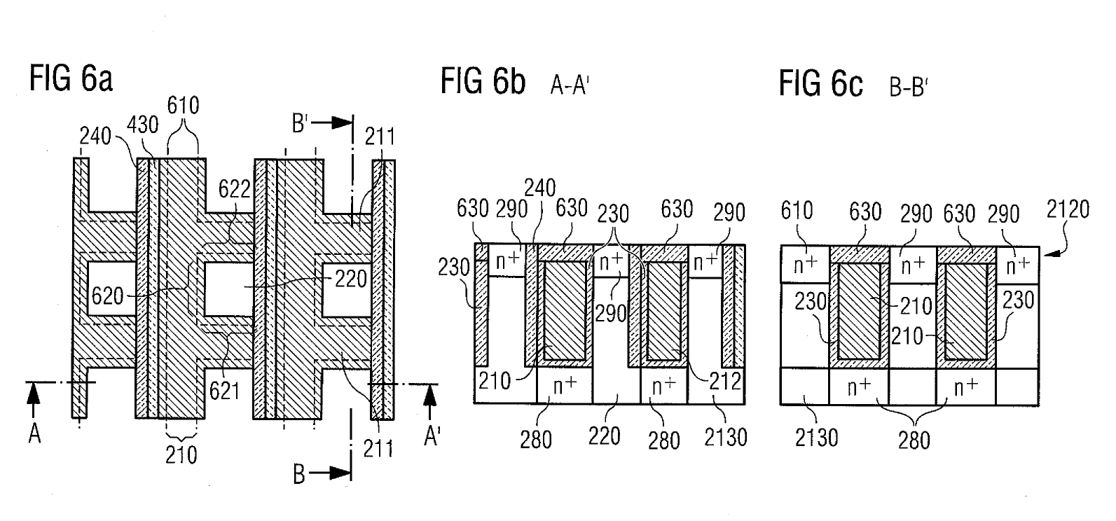

FIGS. 6a, 6b and 6c illustrate the views of the structure after having performed further processing, wherein FIG. 6a is a top view of the structure and FIGS. 6b and 6c are cross sectional views along cut lines A-A′ and B-B′ respectively.

In the illustrated embodiment the oxidized, doped polysilicon 430 has been removed from the sidewall of the word line trench 410, which can be achieved for example by a suitable etch processing. The removal of the oxidized, doped polysilicon at the sidewall increases the cross-sectional area of the word line and thus the conductivity of the word line, i.e. the gate conductor. The word line, i.e. the gate conductor, will thus abut liner 240 as illustrated in FIG. 2b.

However, the oxidized, doped polysilicon 430 not necessarily has to be removed. In this case, i.e. the polysilicon 430 remains on the vertical sidewall of a word line trench, layer 430 increases the distance between a word line and active areas associated with an adjacent word line. Due to the increased distance the influence of a powered word line on the adjacent active areas is reduced.

In further processing, source implants are performed in order to form source areas of the selection transistors. This can be achieved for example by forming a sacrificial oxide, e.g., silicon oxide, and doping the ground of the word line trenches 410 and its protrusions 211 with a suitable dopant to form N+ doped source areas 280 in the substrate at the ground of the word lines in order to couple the transistors to a source electrode. In this way first source/drain areas, in one embodiment source areas, of a first conductivity type, namely N+, are formed. Note that cut line B-B′ runs parallel to and through a word line trench 410, so that the cut line runs through the N+ implanted/doped substrate, i.e. the ground of the wordline. However the N+ implanted areas do not extend completely below the pillars 510 or below the insulating nitride liner 240. In one embodiment, the source can also be formed as a plate like layer resulting in a floating body access device. In this case, the plate formation can already be performed early in the process sequence by a blanket implant even prior to forming the sacrificial trenches.

The sacrificial oxide is then removed and a gate oxide 230, such as for example silicon dioxide (SiO₂), is formed. This is usually done by oxidizing the active area 220 or by depositing a suitable gate dielectric material.

Subsequently gate electrodes and word lines 210, 212 are formed in the word line trench 410 by depositing a suitable conducting material.

In one embodiment a word line 210, 212, i.e. a gate, can be formed by depositing a suitable conducting material in a word line trench, wherein the conducting material may be a metal such as tungsten or a conducting polysilicon. The word line material is then recessed below the top of the pillars 510, i.e. below the reference surface. Subsequently the tops of the trenches are filled with an insulating material, for example such as silicon oxide, to form an oxide cap 630 on the word lines. In this way a word line is embedded in insulating material, in order to insulate the word line, i.e. the gate, from the active area of a selection transistor and from adjacent elements.

In one embodiment—not illustrated in the drawings—the word line may be formed by a word line stack including for example a layer of conducting polysilicon and a layer of a metal connected to the top of the first layer, wherein the second layer may be located above the reference plane.

The word lines 210, 212 and their protrusions 211 are covered by the oxide cap 630, thus they are not visible in the top view. Their location is illustrated by the dotted lines 610, which denote the contour of the word lines.

After the word lines have been covered by the oxide caps 630 the surface of the chip is planarized, for example by a CMP processing step. Afterwards layer 320 of hard mask material is removed by a suitable wet or dry etch and thus the top surface of the pillars 510 of substrate material 2130 is bared.

The top of the vertical pillars can be doped to implant N+ charge carriers, thus the top ends of the pillars form second the source/drain areas 290 of a selection transistor. Similar to the first source/drain areas described above these second source/drain areas are of N+ conductivity type, such that the first and the second source/drain areas are of a first conductivity type.

The doping of pillars 510 is limited to the top such that an area of original substrate material is maintained between the first and second source/drain areas, in which the conducting channel of a transistor is formed. This channel area is of a second conductivity type, as the original substrate 2130 of the chip may be slightly P doped.

FIG. 6a illustrates the structure of the selection transistors. When selecting one of the plurality of transistors, a gate voltage is applied to a word line, which in this example may be word line 210.

The gate voltage effectuates an electrical field at a first side 620 of active area 220 and also at a second side 621 and a third side 622 through protrusions 211, which abut the active area. The transistor may thus be called triple gate transistor or trigate transistor. The conducting channel induced by the electrical field effectuated by the three gates has a lower resistance when compared to a dual gate or single gate transistor thus enabling a higher current through the transistor.

A current through the transistor flows from the source area 280 vertically through active area 220, dissipates the transistor via drain 290 and is then fed into a resistively switching memory element coupled to drain area 290. Generally any resistively switching memory element may be coupled to drain area 290.

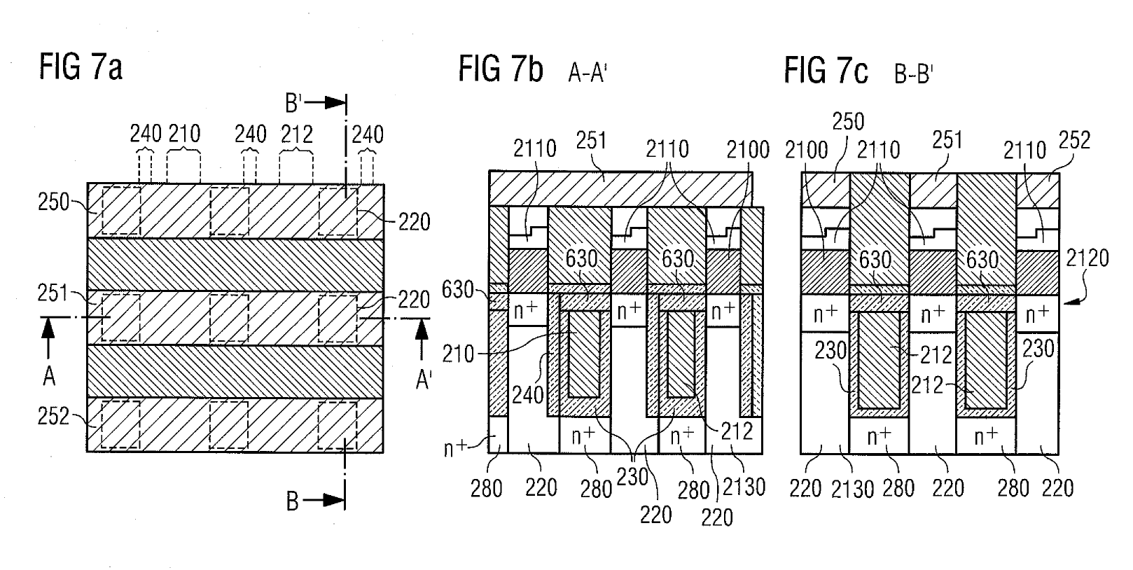

In one embodiment the resistively switching memory element may be a volume of phase change material. FIG. 7 illustrates a top-down view on and cross sections through an array of memory cells including vertical trigate selection transistors and a phase change memory element. Note that FIG. 7a in this top-down view deviates from FIG. 2a, because insulating layers are illustrated. FIG. 7b illustrates a cross section along cut line A-A′, which runs parallel and through a bit line and is thus substantially identical to FIG. 2b. FIG. 7c illustrates a cross section along cut-line B-B′, i.e. parallel and through a word line 210.

Once the structure of the selection transistors has been produced, an insulating middle-of-line (MOL) layer 2140, for example a comparatively thin layer of silicon nitride, and a comparatively thicker layer of silicon oxide 2150 are deposited on the structure. Both layers may be deposited using a chemical vapor deposition method. Then contact holes are etched through the silicon oxide layer 2150 and the MOL liner 2140 in order to contact the drain areas 290 of the selection transistors. The etch can be performed using a conventional etching process. Subsequently the holes are filled with a conducting material to form bottom electrode contacts 2100 After the bottom electrode contacts have been produced the surface of the chip may be planarized by a chemical mechanical polishing method. Volumes of phase change material 2110 forming the memory elements are then produced on top of the bottom electrode contacts 2100 by depositing and subsequently structuring a layer of phase change material on the chip. Then bit lines 250, 251 running perpendicular to the word lines 210, 212 are formed on top of the memory elements, such that the memory cells can be coupled to peripheral logic devices on the memory chip.

In the illustrated embodiments the source of the selection transistors has been produced by implanting N+ ions into the bottom of the word line trenches, forming a mesh-like source electrode plate, which allows coupling of the transistor body to the substrate voltage.

In one embodiment, the source can also be formed as a plate like layer resulting in a floating body access device, as the transistor body is disconnected from the silicon substrate potential. In this case, the plate formation can already be performed early in the process sequence by a blanket implant even prior to forming the sacrificial trenches using conventional processing, for example by deep implanting ions into the substrate thus forming a conducting source plate buried below the transistor structure. In one embodiment the buried source plate may be produced by implanting N+ ions into the surface layer of the substrate and subsequent epitaxial growth of substrate material, e.g., silicon, on the implanted layer.

Performing the afore described processing produces a plurality of memory cells, wherein each memory cell includes a selection transistor at least partially formed in a substrate for selecting one of the plurality of memory cells. Each selection transistor includes a first source/drain region of a first conductivity type, for example here of n conductivity type, which couples the selection transistor to a first electrode, which in this case is the source electrode plate. A second source/drain region of the first conductivity type couples the transistor to a memory element, wherein the coupling may be direct or via a bottom electrode contact as illustrated in the figures. The channel region of the transistor is of a second conductivity type, which in the described embodiment is p type conductivity resulting from the slightly doped substrate, and connects the first source/drain region with the second source drain region. As the channel region is arranged above the first source/drain region and below the second source drain region, the transistor is a vertical transistor. That is the current flowing through the channel region of the vertical selection transistor flows vertically with respect to the original horizontal substrate surface. The gate electrode of the vertical selection transistor is arranged at three sides of the channel region.

While the invention has been particularly illustrated and described with reference to specific embodiments thereof, it will be understood by those skilled in the art that changes in the form and details of the disclosed embodiments may be made without departing from the spirit or scope of the invention. The described embodiments are therefore examples of the invention and should not be understood in a limiting way. It is intended that the invention be interpreted to include all variations and equivalents that fall within the true spirit and scope of the present invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit including an array of selection transistors at least partially formed in a substrate for selecting one of a plurality of memory cells, a selection transistor comprising:
a first source/drain region of a first conductivity type coupling the transistor to a first electrode;
a second source/drain region of the first conductivity type coupling the transistor to a memory element;
a channel region of a second conductivity type connecting the first source/drain region with the second source/drain region, wherein the channel region is arranged above the first source/drain region and below the second source/drain region; and
a gate electrode arranged at three sides of the channel region.

2. The integrated circuit of claim 1, wherein the gate electrode has the shape of a line having protrusions in one direction, and a channel region is arranged between a first and second, adjacent protrusion of the gate electrode.

3. The integrated circuit of claim 1, wherein the residual side of the channel region abuts an insulating liner, wherein the insulating liner separates protrusions of a gate electrode from an adjacent gate electrode.

4. The integrated circuit of claim 1, wherein the first source/drain region is coupled to a source electrode.

5. The integrated circuit of claim 4, wherein the source electrode is a source plate electrode arranged below the first/source drain electrode.

6. The integrated circuit of claim 4, wherein the source electrode is shaped like a mesh.

7. The integrated circuit of claim 1, wherein the second source/drain area is coupled to a memory element.

8. The integrated circuit of claim 7, wherein the memory element is a volume of resistively switching active material.

9. The integrated circuit of claim 8, wherein the switching active material is a phase change material.

10. The integrated circuit of claim 8, wherein the switching active material is a magneto resistive material.

11. The integrated circuit of claim 1, wherein a plurality of memory cells is coupled to a bit line and the bit line intersects the word line.

12. The integrated circuit of claim 1, wherein the word line is formed from a single conductive material.

13. The integrated circuit of claim 1, wherein the word line is formed as a stack comprising at least two layers of different conducting material.

14. A memory device comprising an integrated circuit according to claim 1.

15. A method of forming an integrated circuit including an array of transistors in a substrate for selecting one of a plurality of resistively switching memory cells, comprising:
providing a substrate;
forming a plurality of parallel, auxiliary trenches in the substrate and filling the auxiliary trenches with a sacrificial material;
forming a plurality of gate electrode trenches intersecting the auxiliary, filled trenches, wherein the sacrificial material in the auxiliary trenches is removed at intersections of auxiliary trenches and gate electrode trenches;
forming an insulating liner at one sidewall of the gate electrode trenches;
removing the sacrificial material from the auxiliary trenches, the portions of the auxiliary trenches thus forming protrusions of the gate electrode trenches;
forming first source/drain regions in the bottom of the gate electrode trenches;
forming gate electrodes in the gate electrode trenches and their protrusions; and
forming second source/drain regions in the pillars of substrate material located between the protrusions of the gate electrode.

16. The method of claim 15, wherein prior to forming the auxiliary trenches a source plate electrode is formed in the substrate.

17. The method of claim 16, wherein the source plate electrode is formed by deep implanting ions into the substrate to form a buried plate electrode.

18. The method of claim 16, wherein the source plate electrode is shaped like a mesh.

19. The method of claim 15, wherein forming an insulating liner at one sidewall of the gate electrode trenches comprises
depositing a first liner of insulating material in the gate electrode trenches;
depositing a second layer of material on the first liner;
doping the second layer by an angled implant on at least one sidewall;
removing the undoped second layer material; and
removing the first liner where bared.

20. The method of claim 19, comprising removing the doped, second layer material from the first liner.

21. The method of claim 19, comprising oxidizing the doped, second layer material on the one sidewall.

23. The method of claim 15, wherein forming first source/drain regions comprises implanting N+ ions into the bottom of the gate electrode trenches.

24. The method of claim 15, wherein forming second source/drain regions comprises implanting N+ ions into the substrate material located between the protrusions of the gate electrode.
